(19) United States
(12) Patent Application Publication
(10) Pub. No.: US 2024/0093378 A1
(43) Pub. Date: Mar. 21, 2024

(54) Method for Producing a Coated Body as Well as Coated Body Obtainable According to the Method

(71) Applicant: KENNAMETAL INC., Latrobe, PA (US)

(72) Inventors: Joern Kohlscheen, Ebermannstadt (DE); Christian Bareiss, Ebermannstadt (DE); Horst Jaeger, Fuerth (DE); Patrick Kuhlemann, Fuerth (DE); Christoph Gey, Neuhausen am Rheinfall (CH)

(21) Appl. No.: 18/370,499

(22) Filed: Sep. 20, 2023

(30) Foreign Application Priority Data
Sep. 21, 2022 (DE) 102022124181.5

(51) Int. Cl. C23C 28/04; B23B 27/14; C23C 14/06; C23C 14/35

(52) U.S. Cl. CPC C23C 28/044; B23B 27/148; C23C 14/0635; C23C 14/0641; C23C 14/0664; C23C 14/35; B23B 2224/32

(57) ABSTRACT

The invention relates to a method for producing a coated body, with a substrate and a coating arranged on the substrate, which coating comprises at least one base layer applied to the substrate and at least one metal carbide-containing layer arranged over the base layer, which layers are applied by means of magnetron sputtering. Furthermore, the invention relates to a coated body produced according to the method.

### RELATED APPLICATION DATA

The present application claims priority under 35 U.S.C. § 119 to German Patent Application No. 102022124181.5, filed on Sep. 21, 2022, the disclosure of which is incorporated by reference herein in its entirety.

### FIELD

The present invention relates to a method for producing a coated body as well as a coated body that can be obtained according to the method.

### BACKGROUND

Generally, suitable cutting tools bearing a wear-resistant coating are used for machining workpieces made of steel and cast iron. Such coated cutting tools typically consist of a base body and a coating applied to the base body, which can comprise one or more layers of hard materials such as titanium nitride, titanium carbide, titanium carbonitride, titanium aluminum nitride, and/or aluminum oxide.

Such coatings make the cutting insert of the cutting tool harder and thus more wear-resistant, thereby improving the cutting properties of the cutting tool. The coatings are typically applied by methods of both chemical vapor depositing (CVD) as well as physical vapor depositing (PVD).

Typically, PVD methods such as arc vaporizing (Arc-PVD) and cathode atomizing (sputtering) are used. In sputtering, a substrate and a target (cathode) are arranged opposite one another in a closed chamber. Gas discharge produces a plasma as an ion source within the chamber. The ions from the plasma bombard the target (cathode) and strike atoms out of it, which are deposited on the oppositely arranged substrate and form a layer thereon.

Such PVD methods are also employed in order to deposit titanium nitride and titanium aluminum nitride, wherein both DC voltage and pulsed electric voltage are used on the cathodes in order to reduce a poisoning of the metal targets by the electrically non-conductive cathodes. The voltage-pulsed supply of the cathodes is generally ensured with two magnetic atomization sources that are connected to a sinusoidal generator in such a way that the two magnetic atomization sources act alternately as an anode and cathode of the sputtering arrangement at a particular pulse frequency.

In the production of coatings of bodies for cutting tools, there is increasing concern for producing harder coatings. For this reason, coatings are reinforced by thin layers of aluminum titanium nitride (AlTiN) and/or titanium carbide (TiC).

One method for producing such layers is high-power pulse magnetron sputtering (HiPIMS). Compared to the cathode atomization described above, HiPIMS uses very high cathode power densities with very short electrical pulses, which can produce a high degree of ionization of the target material with a simultaneously high gas ionization.

From US 2021/0 395 875A1 and WO 2019/048507 A1, HiPIMS methods are known for the depositing of aluminum-rich AlₓTi₁₋ₓN-containing coatings having an aluminum content >75 atom %. It is disclosed that, during the HiPIMS method, a constant negative voltage is applied to the substrate.

WO 2019/025 629A1 discloses a drill head consisting of a substrate and a wear-resistant coating arranged on the substrate, which consists of a layer containing (AlCr)N. A second layer consisting of a metal carbide, in particular a titanium carbide, can be arranged on this layer. The second layer is prepared by means of a HiPIMS method, wherein a titanium target or a titanium carbide target is used for the HiPIMS method.

Furthermore, a coating for a cutting tool is known from US 2014/0 248 100A1, wherein the coating comprises at least one layer produced by means of a HiPIMS method. In particular, the layer consists of at least one nitride and/or carbide layer, preferably comprising a metal selected from the group consisting of chromium, titanium, aluminum, and tungsten.

Also known from the scientific article by Katalin Balazsi (Vacuum 164 (2019) 121-125) is a magnetron sputtering method for the depositing of thin nanocomposite layers consisting of TiC/a:C. The disclosed method includes the provision of two separate titanium and graphite targets. The layers were deposited at a temperature of 25 to 800° C. as well as under an argonated atmosphere (2.5×10⁻³ mbar). The graphite target was supplied with a constant power of 150 W. With the method described, TiC/a:C coatings were produced having different titanium contents. Layers having a titanium content of 30 atom % (40 W of the titanium target) demonstrated a hardness of 26 GPa as well as an elastic modulus of 140 GPa.

A similar method for producing TiC/a:C coatings using a pulsed magnetron sputtering method is described by J. Lin et al. in another scientific article (Thin Solid Films 517 (2008) 1131-1135). In the article, the authors disclose a method for producing TiC/a:C coatings, wherein the depositing of the coatings occurs through spatially separated titanium and graphite targets. The target power was varied between 200 and 1400 W, while the substrate was held under a constant negative voltage of −50 V at a depositing temperature of 250° C. During depositing, the titanium target was operated in a pulsed mode at a frequency of 100 kHz, while the graphite target was powered by DC power. Coatings having a hardness of 24-29 GPa and a friction coefficient of 0.24-0.25 as well as a wear rate of 2.5×10⁻⁷ mm³ N⁻¹ m⁻¹ were thus produced. The carbon content of the coatings ranged from 55-66 atom %.

The invention therefore addresses the problem of providing a method with which further coatings for cutting tools can be produced, having improved performance in terms of metal machining and metal alloys.

### SUMMARY

According to the present invention, the problem is solved by means of a method for producing a coated body according to claim 1.

Advantageous embodiments of the method according to the invention for producing a coated body are specified in the subclaims, which can optionally be combined with one another.

According to the invention, a method is provided for producing a coated body having a substrate and a coating arranged on the substrate, which coating comprises at least one base layer applied to the substrate and at least one metal carbide-containing layer arranged over the base layer,
wherein the base layer is formed from a nitride of aluminum and at least one further metal, and wherein the further metal is selected from the group consisting of Ti, Cr, Si, Zr as well as combinations thereof,
wherein the metal carbide-containing layer comprises at least one carbide of a metal selected from the group consisting of titanium, vanadium, chromium, niobium, molybdenum, tantalum, and tungsten, as well as combinations thereof,
wherein the metal carbide-containing layer has a carbon content in a range of 40-65 atom %.

The method according to the invention comprises the following steps:
applying the base layer to the substrate, wherein, during the application of the base layer, a pulsed voltage is applied to the substrate in a range of −50 to −200 V; and
applying the metal carbide-containing layer over the base layer by means of magnetron sputtering, wherein the substrate is held under a constant voltage in a range of −50 to −200 V during the application of the metal carbide-containing layer, and wherein the metal carbide-containing layer is applied using a graphite target on a metal target separated from the graphite target.

The invention is based on the finding that, with the above-mentioned method, coatings can be produced from metal carbide-containing layers that have a higher hardness than comparable coatings from the prior art, as well as a lower friction coefficient in addition. Surprisingly, the inventors have found that such hard coatings only form when a pulsed voltage in a range of −50 to −200 V is applied to the substrate during the application of the base layer and a constant voltage in a range of −50 to 200 V is applied to the substrate during the application of the metal carbide-containing layer. In other words, by contrast to known methods of the prior art, in which a constant negative voltage is applied to the substrate, a pulsed voltage is now used on the substrate during the application of the base layer. Thus, a base layer can be produced that has particularly low mechanical voltages, because the exposure occurs during layer growth in the pulsed mode (i.e. interrupted and not constant). In combination with a metal carbide-containing layer, which is applied at a constant voltage, coatings can be obtained that have a higher hardness and a higher wear resistance than known coatings from the prior art.

Substrates suitable for producing the coated body according to the invention are known. For example, the substrate can be made of a carbide, cermet, cubic boron nitride, steel, or high-speed steel.

During the depositing of the coating, the temperature of the substrate is preferably held in a range of 500 to 600° C., further preferably between 450 and 550° C. This allows the formation of a particularly homogeneous layer as well as better adhesion to the substrate.

Advantageously, an argon partial pressure in a range of 0.1 to 0.8 Pa is used during the application of the coating, preferably 0.3 to 0.5 Pa. Argon is a common gas known from the prior art for sputtering methods, which allows the use of argon to draw on known process specifications.

Advantageously, during the application of the base layer, a pulsed voltage is applied to the substrate in a range of −50 to −150 V, preferably −90 to −120 V. By applying a negative voltage, a compression of the coating can advantageously be achieved during the application.

According to a further aspect, during the application of the base layer to the substrate, a pulsed voltage is applied with a frequency in a range of 1 to 6 kHz, preferably 3 to 5 kHz. The pulses used can have a pulse length in a range of 30 to 100 μs, preferably 50 to 80 μs.

According to one aspect, the substrate is held under a constant voltage in a range of −80 to −200 V, particularly preferably −100 to −150 V, during the application of the metal carbide-containing layer.

Another aspect provides that the metal target is a titanium target. Accordingly, the metal carbide-containing layer is a titanium carbide-containing layer.

Advantageously, the application of the titanium carbide-containing layer occurs in a pulsed mode, wherein the mode actuates the graphite target and the titanium target, respectively, with electrical pulses having a frequency in a range of 0.1-5 kHz, preferably 0.5-2 kHz.

According to a further aspect, the application of the titanium carbide-containing layer occurs in a pulsed mode, wherein the pulsed mode electrical pulse of the pulsed mode has a temporal length in a range of 20 to 200 μs, preferably 40 to 100 μs. Here, pulse length means the time interval in which the power is released (so-called “on-time”).

Advantageously, the titanium target and the graphite target are each operated at a mean cathode energy in a range of 2 to 8 kW, preferably 4 to 6 kW, during the application of the metal carbide containing layer.

Because the targets are operated in a pulsed mode, the input of the cathode energy occurs only during the pulse length, thereby releasing a significantly higher energy. Insufficient ionization of the graphite target often presents a problem in the depositing of carbon from a graphite target. However, due to the predetermined clocking of the pulses, a higher energy input on the target can occur, so that a higher ionization rate of the material to be deposited is achieved without the target being prone to overheating.

In a preferred embodiment, the magnetron sputtering method is a high-power impulse magnetron sputtering (HiPIMS) method. Such a method offers the advantage that, due to the use of pulses, a high energy input can occur on the targets in a short time. Thus, a high degree of ionization of the target material, in particular the graphite target, can be achieved. Because the pulses only act on the target material in a short period of time, a low average cathode performance results overall at a simultaneously high pulse frequency. In this way, cooling of the targets during the process can be ensured, thereby increasing the overall stability of the method.

The subject matter of the invention is furthermore a coated body having a substrate and a coating arranged on the substrate, which coating comprises at least one base layer applied to the substrate and at least one metal carbide-containing layer arranged over the base layer. Thus, the base layer is arranged between the metal carbide-containing layer and the substrate, which can also be referred to as the top layer. The base layer is formed from a nitride of aluminum and at least one further metal, wherein the further metal is selected from the group consisting of Ti, Cr, Si, Zr as well as combinations thereof. The metal carbide-containing layer comprises at least one carbide of a metal selected from the group consisting of titanium, vanadium, chromium, niobium, molybdenum, tantalum, and tungsten, as well as combinations thereof. The metal carbide-containing layer has a carbon content in a range of 40-65 atom %. The body can be obtained by the method described above.

Advantageously, the base layer is applied to the substrate by means of the magnetron sputtering method, such that the base layer experiences particularly low mechanical voltages during its production. The base layer thus also has particularly low mechanical voltages even after production. This is in particular achieved by the method step in which a pulsed voltage is applied to the substrate while the base layer is deposited on the substrate.

The base layer applied according to the invention causes a particularly good connection of the metal carbide-containing layer to the substrate. In addition, a synergistic effect results from the low-tension base layer and the hard, yet low-friction, metal carbide-containing layer, thereby forming an overall low-friction yet wear-resistant coating.

Preferably, the metal carbide-containing layer has a carbon content in a range of 40-65 atom %, particularly preferably 45-55 atom %. Such a layer is particularly wear-resistant. Moreover, a low friction coefficient is enabled due to the presence of unbonded carbon. Unbonded carbon is preferably deposited as a soft graphite during depositing, thus allowing for the desired friction reduction. The metal carbide present in the layer is predominantly crystalline metal carbide. The metal carbide crystallites can be embedded in a carbon matrix. The carbon matrix can comprise amorphous or graphitic carbon. A mixture of amorphous and graphitic carbon is also contemplated.

According to a further aspect, an intermediate layer is provided between the metal carbide-containing layer and the base layer, wherein the intermediate layer is formed from a carbonitride of aluminum and at least one further metal, wherein the further metal is selected from the group consisting of titanium, chromium, silicon, zirconium, as well as combinations thereof.

Preferably, the intermediate layer is formed from an aluminum titanium carbonitride.

Such an intermediate layer has a nitride percentage compatible with the base layer as well as a titanium carbide percentage compatible with the metal carbide-containing layer. In this way, both layers can be particularly well connected to one another. Furthermore, by inserting an intermediate layer, the wear resistance of the coating can be further improved. In addition, a particularly good adhesion between the base layer and the metal carbide-containing layer can be achieved with the intermediate layer.

According to a further aspect, the intermediate layer comprises at least one exchange layer of a carbonitride layer and a nitride layer arranged over the carbonitride layer wherein the carbonitride layer is formed from a carbonitride of aluminum and at least one further metal selected from the group consisting of titanium, chromium, silicon, zirconium, as well as combinations thereof, and wherein the nitride layer is formed from a nitride of aluminum and at least one further metal selected from the group consisting of titanium, chromium, silicon, zirconium, as well as combinations thereof.

In a particularly preferred embodiment, the carbonitride layer is formed from aluminum titanium carbonitride and/or the nitride layer is formed from aluminum titanium nitride.

In principle, the number of repetitions of the exchange layers is arbitrary and not limited. In a preferred embodiment, the intermediate layer has 1 to 10 repetitions of the at least one exchange layer consisting of the carbonitride layer and nitride layer, preferably 3 to 5 repetitions.

According to a further aspect, an intermediate layer is provided between the metal carbide-containing layer and the base layer, wherein the intermediate layer is formed from a carbonitride of a metal, wherein the metal is selected from the group consisting of titanium, chromium, silicon, zirconium, and combinations thereof.

Preferably, the intermediate layer according to this aspect is formed from a titanium carbonitride.

According to a further aspect, the intermediate layer comprises at least one exchange layer of a carbonitride layer and a nitride layer arranged over the carbonitride layer, wherein the carbonitride layer is formed from a carbonitride of a metal selected from the group consisting of titanium, chromium, silicon, zirconium, as well as combinations thereof, and wherein the nitride layer is formed from a nitride of aluminum and at least one further metal selected from the group consisting of titanium, chromium, silicon, zirconium, as well as combinations thereof.

According to a further aspect, the carbonitride layer is formed from titanium carbonitride and/or the nitride layer is formed from aluminum titanium nitride.

In principle, the number of repetitions of the exchange layers is arbitrary and not limited. In a preferred embodiment, the intermediate layer has 1 to 10 repetitions of the at least one exchange layer consisting of the carbonitride layer and nitride layer, preferably 3 to 5 repetitions.

By inserting an alternating exchange layer consisting of carbonitride and nitride layers, a particularly hard coating can be produced, which is also resistant at high temperatures. In this way, the hardness of the coating can be further improved compared to layers without an exchange layer.

In a preferred embodiment, the metal carbide-containing layer is a titanium carbide-containing layer. The metal carbide-containing layer thus comprises titanium carbide and unbonded carbon.

Preferably, the metal carbide-containing layer comprises titanium crystalline carbide, more specifically cubic titanium carbide, in which the reflex (200) can be detected by means of X-ray structure analysis.

According to a further aspect, the titanium carbide-containing layer has a plastic hardness in a range of 25 to 50 GPa, preferably 30 to 50 GPa, particularly preferably 35 to 45 GPa. The plastic hardness is measured by the following method: instrumented hardness or penetration test in accordance with DIN ISO 14577-1.

According to a further aspect, the titanium carbide-containing layer has an elasticity modulus in a range from 200 to 500 GPa, preferably from 300 to 500 GPa, particularly preferably from 350 to 450 GPa. The elasticity modulus is also determined in accordance with DIN ISO 14577-1.

A further aspect provides that the substrate is a cutting insert or tool holder.

The tool holder can have a receiving space having at least one surface which, when a tool is clamped in the tool holder, is in direct contact with the tool, wherein at least one surface bears with the coating as described above.

In principle, any surface of the tool holder that comes into direct contact with the tool when a tool is clamped can be coated.

According to a further aspect, the at least one surface is a clamping surface, a base surface, a torque transfer surface, or an abutment surface.

The coating of a tool holder with the coating described above makes it more wearable overall. In particular, due to the trend of giving tools increasingly wear-resistant, i.e. harder, coatings, it is advantageous to also coat the tool holder with a hard and wear-resistant coating in order to design it more resiliently in relation to the tool. Thus, the wear experienced by the tool holder through direct contact with the tool can be significantly reduced.

### DESCRIPTION OF THE DRAWINGS

The invention will be described in further detail below with reference to the accompanying drawings, using exemplary embodiments. The drawings show:

FIG. 1 in a schematic view, the construction of a coated body having a substrate and a coating arranged on the substrate;

FIG. 2 in a schematic view, the construction of a further coated body having a substrate and a coating arranged on the substrate, wherein the coating comprises an exchange layer;

FIG. 3 the plastic hardness and elasticity modulus made of different titanium and carbon compositions (varying from position 1 to 10); and

FIG. 4 a schematic view of a cutting tool holder.

### DETAILED DESCRIPTION

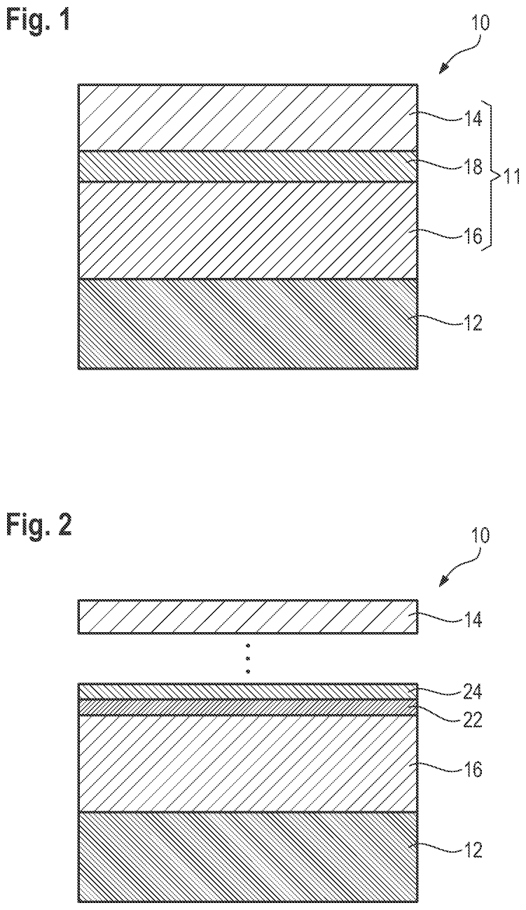

FIG. 1 shows the construction of a coated body produced according to the above-mentioned method.

The coated body 10 is a component part of a cutting tool. In particular, the coated body 10 can be the cutting insert of a cutting tool that is provided for the machining of workpieces.

The coated body 10 comprises a substrate 12.

The substrate 12 is typically a material selected from the group consisting of carbide, cermet, cubic boron nitride, steel, high-speed steel, and combinations thereof.

A coating 11 is arranged on the substrate 12.

The coating 11 comprises a metal carbide-containing layer 14, an intermediate layer 18, and a base layer 16.

The coating 11 arranged on the substrate 12 preferably has a thickness in a range of 1 to 10 μm, preferably from 2 to 6 μm, particularly preferably from 3 to 5 μm.

The composition of the individual layers as well as their arrangement will be explained in further detail below.

A base layer 16 is arranged adjacent to the substrate 12.

The base layer 16 consists of a nitride of aluminum and at least one further metal, wherein the further metal is selected from the group consisting of titanium, chromium, silicon, zirconium, as well as combinations thereof.

Preferably, the base layer 16 is aluminum titanium nitride.

The base layer 16 arranged on the substrate 12 preferably has a thickness in a range of 1 to 8 μm, preferably from 1 to 5 μm, particularly preferably from 2 to 4 μm.

An intermediate layer 18 is arranged on a side of the base layer 16 facing away from the substrate 12.

The intermediate layer 18 in particular consists of a carbonitride of aluminum and at least one further metal, wherein the further metal is selected from the group consisting of titanium, chromium, silicon and zirconium, as well as combinations thereof.

Particularly preferably, the intermediate layer 18 is formed from aluminum titanium carbonitride.

Alternatively, the intermediate layer 18 can be formed from a carbonitride of a metal, wherein the metal is selected from the group consisting of Ti, Cr, Si, Zr, as well as combinations thereof.

In this variant, the intermediate layer 18 is formed from titanium carbonitride.

The intermediate layer 18 arranged on the base layer 16 preferably has a thickness in a range of 0.5 to 6 μm, preferably from 1 to 4 μm, particularly preferably from 2 to 4 μm.

The metal carbide-containing layer 14 is arranged on a side of the intermediate layer 18 facing away from the base layer 16. The intermediate layer 18 is thus formed between the base layer 16 and the metal carbide-containing layer 14. Thus, the intermediate layer 18 connects the base layer 16 to the metal carbide-containing layer 14.

The metal carbide-containing layer 14 comprises at least one carbide of a metal selected from the group consisting of titanium, vanadium, chromium, niobium, molybdenum, tantalum, and tungsten, as well as combinations thereof. Preferably, it is a titanium carbide-containing layer.

Furthermore, the metal carbide-containing layer 14 has a carbon content in a range of 40-65 atom %.

The metal carbide-containing layer 14 arranged on the intermediate layer 18 preferably has a thickness in a range from 0.1 to 3 μm, preferably from 1 to 3 μm, particularly preferably from 1 to 2 μm.

Preferably, the metal carbide-containing layer 14 is the outermost layer of the coating 11.

The aforementioned layers were applied to the substrate by means of a magnetron sputtering method, in particular by means of a high-power impulse magnetron sputtering (HiPIMS) method.

FIG. 2 shows a coated body 10 with an alternative construction of the coating 11.

Unlike FIG. 1, in FIG. 2, the intermediate layer 18 forms an exchange layer 20. The exchange layer 20 is arranged between the base layer 16 and the metal carbide-containing layer 14.

The exchange layer 20 comprises at least one carbonitride layer 22 arranged over the base layer 16 as well as a nitride layer 24 arranged over the carbonitride layer 22. The nitride layer 24 is thus arranged between the metal carbide-containing layer 14 and the carbonitride layer 22.

The exchange layer 20 preferably has 1 to 10 repetitions consisting of the carbonitride layer 22 or nitride layer 24. Preferably, the exchange layer has 3 to 5 repetitions.

The carbonitride and nitride layers 22, 24 of the exchange layer 20 are also produced by means of a magnetron sputtering method, in particular by means of a high-power impulse magnetron sputtering (HiPIMS) method.

The carbonitride layer 22 consists of a carbonitride of aluminum and at least one further metal selected from the group consisting of titanium, chromium, silicon, zirconium, as well as combinations thereof.

Particularly preferably, the carbonitride layer 22 is formed from aluminum titanium carbonitride.

The carbonitride layer 22 preferably has a thickness of 0.02 to 1 μm, preferably from 0.02 to 0.5 μm, particularly preferably from 0.05 to 0.2 μm.

Alternatively, the carbonitride layer 22 can be formed from a carbonitride of a metal selected from the group consisting of Ti, Cr, Si, Zr, as well as combinations thereof.

In this variant, the carbonitride layer 22 is preferably formed from a titanium carbonitride.

The nitride layer 24 is formed from a nitride of aluminum and at least one metal selected from the group consisting of titanium, chromium, silicon, zirconium, as well as combinations thereof.

Particularly preferably, the nitride layer 24 is formed from aluminum titanium nitride.

The nitride layer 24 preferably has a thickness of 0.02-1 μm, preferably from 0.02 to 0.5 μm, particularly preferably from 0.05 to 0.2 μm.

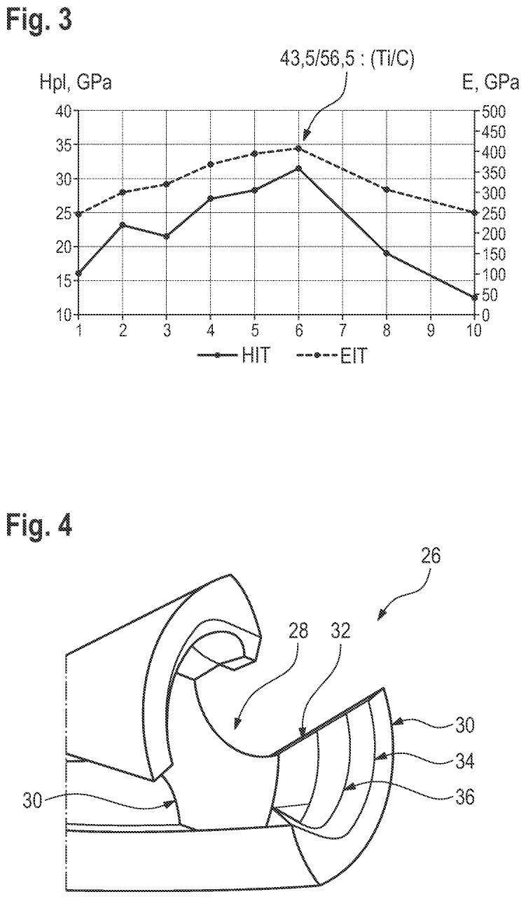

FIG. 3 shows a measurement plot of 10 different titanium carbide-containing layers, wherein the layers differ from one another with respect to their Ti:C ratio.

The produced coatings each comprise a substrate and the titanium carbide-containing coating.

The substrate consisted of a carbide having a binder content of 6 wt. % cobalt and 94 wt. % tungsten carbide.

The measurement diagram shows the plastic hardness (Hpl) and the elasticity modulus (E) as mechanical characteristic values of the respective titanium carbide-containing coatings, whose composition was varied from position 1 to 10 (position 1 was carbon-rich, position 10 was titanium-rich).

The plastic hardness and the elasticity modulus were determined as described above.

As can be seen from the measurement plot of FIG. 3, the coating of position no. 6 has a particularly high plastic hardness as well as a particularly high elasticity modulus. The plastic hardness is 31.5 GPa, and the elasticity modulus is 407 GPa. At the same time, coating no. 6 represents the coating having the highest measured plastic hardness and elasticity modulus.

Coating no. 6 has a titanium content of 43.5 atom % and a carbon content of 56.5 atom %. The proportion of titanium and carbon was measured by energy-dispersive x-ray spectroscopy (EDX), taking into account only these two elements. The measurement was taken in view of the sample surface with 15 kV excitation and 60 s exposure time (meter: phenom XL).

FIG. 4 shows a tool holder 26 for receiving a tool (not shown here).

The tool holder 26 defines a receiving space 28, which is configured so as to receive a tool, for example a drill. The receiving space 28 has surfaces that can come into contact with a tool upon clamping of a tool.

More particularly, the receiving space 28 has a base surface 30, a torque transfer surface 32, an abutment surface 34, and a clamping surface 36. These surfaces can be given a coating 11 as mentioned above (not shown here).

The base surface 30 is the surface forming the face of the tool holder 26.

The torque transfer surface 32 is the surface that applies torque to the tool during machining operation.

If a tool is clamped in the tool holder, it is fixed in position by the clamping surface 36.

The abutment surfaces 34 refer to all other surfaces that are in contact with the tool and cannot be subsumed by the above surfaces.

### DESCRIPTION OF EXEMPLARY EMBODIMENTS

The invention will be explained below by way of examples, which are not to be construed in a limiting sense.

### PRODUCTION EXAMPLES

### Example 1

In a HiPIMS coating system of the type CC800 by the company Cemecon AG, a substrate (after cleaning and roughening by microjets with corundum powder) for a cutting tool made of carbide (with 6 wt. % cobalt binder, 94 wt. % WC) was given a base layer of AlTiN, hereinafter referred to as the base layer, and a titanium carbide-containing layer. The parameters used for depositing the individual layers during the method can be found in Table 1.

A cathode having a composition of titanium (pure) and a cathode of graphite (pure) were used for depositing the individual layers. Nitrogen was added as a gas (reactive process guidance). As a working/sputtering gas, argon was added according to the prior art.

A plastic hardness of 37.6 GPa was measured for the base layer produced in this way. The titanium carbide-containing layer has a plastic hardness of 25.2 GPa.

### Example 2 (Reference)—Variant 1a

The substrates, pretreatment, and coating equipment are the same as in the example above. A base layer of AlTiN was conventionally deposited in the DC sputtering method. The metal carbide layer was deposited analogously to the metal carbide layer in the example according to the invention, with the difference that, during depositing, the cathode and the substrate were not pulsed. The parameters used for depositing the individual layers during the method can also be found in Table 1.

A plastic hardness of 33.6 GPa was measured for the base layer. The titanium carbide-containing layer has a plastic hardness of 21.5 GPa.

### Example 3 (Reference)—Variant 1c

The substrates, pretreatment, and coating equipment are the same as in the example above. A base layer of AlTiN was conventionally deposited in the DC sputtering method. The metal carbide layer was deposited analogously to the metal carbide layer in the example according to the invention, with the difference that, during depositing, the cathode and the substrate were pulsed. The parameters used for depositing the individual layers during the method can also be found in Table 1.

A plastic hardness of 33.6 GPa was measured for the base layer. The titanium carbide-containing layer has a plastic hardness of 16 GPa.

TABLE 1
Overview of layer variations and key process parameters used.

| | Variant - 1b | Variant - 1a | Variant - 1c |
|---|---|---|---|
| Parameters | Example 1 | Example 2 | Example 3 |
| Base Layer | TiAIN | TiAIN | TiAIN |
| Layer thickness [μm] | 3.6 | 3.6 | 3.3 |
| Pulse frequency [Hz] | 4000 | DC | DC |
| Pulse duration [μs] | 50 | — | — |
| Power [kW] | 10 | 9 | 9 |
| Substrate voltage [V] | 100 (pulsed) | 100 (constant) | 100 (constant) |
| Plastic hardness [GPa] | 37.6 | 33.6 | 33.6 |
| Metal carbide layer | TiC | TiC | TiC |
| Layer thickness [μm] | 1.3 | 1.2 | 1.5 |
| Pulse frequency [Hz] | 4000 | DC | 4000 |
| Pulse duration [μs] | 50 | — | 50 |
| Power [kW] | 2/5 (pulsed) | 2/5 (constant) | 2/5 (pulsed) |
| Substrate voltage [V] | 100 (constant) | 100 (constant) | 100 (pulsed) |
| Plastic hardness [GPa] | 25.2 | 21.5 | 16 |

Milling Tests 1 to 3:

In milling tests on a workpiece made of grade 1.4322 steel, a cutting tool with a coating according to Example 1 according to the invention having a cutting plate geometry HNGJ0905ANSN-GD was used (milling test 1).

The same milling tests were performed with cutting tools bearing a coating according to Example 2 (milling test 2) and Example 3 (milling test 3).

A milling machine was operated in a toothing test at a cutting speed vc of 250 mpm, a cutting depth ap of 0.6 mm, and an engagement width ae of 33.5 mm. The tooth feed fz was 0.3 mm/U. Milling was done dry, without cooling.

Overall, free-surface wear of the respective coated cutting tools was determined after 3, 6, 9 and 12 passes, wherein a pass corresponds to 300 mm milling length in each case.

Coated cutting tools were used in order to determine the free-surface wear shown in Table 2.

After the twelfth pass, a free-surface wear of 0.09 mm was determined for the coating of Example 1 according to the invention. Thus, the coating of Example 1 according to the present invention demonstrates a lower free-surface wear by 33% compared to Example 3 (0.12 mm) and a lower free-surface wear compared to Example 2 by 177% (0.25 mm). Consequently, the coating according to the invention demonstrates significantly reduced free-surface wear compared to the reference examples.

TABLE 2
Overview of milling tests 1-3

| | Free-surface wear | | | | |
|---|---|---|---|---|---|
| Passes | 0 | 3 | 6 | 9 | 12 |
| Milling test 1 | 0 mm | 0.06 mm | 0.06 mm | 0.08 mm | 0.09 mm |
| Milling test 2 | 0 mm | 0.07 mm | 0.09 mm | 0.12 mm | 0.25 mm |
| Milling test 3 | 0 mm | 0.06 mm | 0.08 mm | 0.11 mm | 0.12 mm |

Milling Tests 4 to 6:

In milling tests on a workpiece made of grade 0.7060 steel, a cutting tool with a coating according to Example 1 according to the invention having a cutting plate geometry HNGJ0905ANSN-GD was used (milling test 4).

The same milling tests were performed with cutting tools bearing a coating according to Example 2 (milling test 5) and Example 3 (milling test 6).

A milling machine was operated in a toothing test at a cutting speed vc of 250 mpm, a cutting depth ap of 2 mm, and an engagement width ae of 33.5 mm. The tooth feed fz was 0.3 mm/U. Milling was done dry, without cooling.

Overall, free-surface wear of the respective coated cutting tools was determined after 0, 6, 12, 18, 24, 30 and 36 passes, wherein a pass corresponds to 300 mm milling length in each case.

Coated cutting tools were used in order to determine the free-surface wear shown in Table 3.

After the 36th pass, a free-surface wear of 0.1 mm was determined for the coating of Example 1 according to the invention. Thus, the coating of Example 1 according to the present invention demonstrates a lower free-surface wear by 280% compared to Example 3 (0.38 mm) and a lower free-surface wear compared to Example 2 by 120% (0.22 mm). Consequently, the coating according to the invention demonstrates significantly reduced free-surface wear compared to the reference examples.

TABLE 3
Overview of milling tests 4-6

| | Free-surface wear | | | | | | |
|---|---|---|---|---|---|---|---|
| Passes | 0 | 6 | 12 | 18 | 24 | 30 | 36 |
| Milling test 4 | 0 mm | 0.03 mm | 0.03 mm | 0.04 mm | 0.04 mm | 0.05 mm | 0.1 mm |
| Milling test 5 | 0 mm | 0.04 mm | 0.04 mm | 0.06 mm | 0.07 mm | 0.1 mm | 0.22 mm |
| Milling test 6 | 0 mm | 0.03 mm | 0.04 mm | 0.06 mm | 0.08 mm | 0.13 mm | 0.38 mm |

1. A method for producing a coated body, wherein the body comprising a substrate and a coating arranged on the substrate, which coating comprises at least one base layer applied to the substrate and at least one metal carbide-containing layer arranged over the base layer,
wherein the base layer is formed from a nitride of aluminum and at least one further metal, wherein the further metal is selected from the group consisting of Ti, Cr, Si, Zr as well as combinations thereof,
wherein the metal carbide-containing layer comprises at least one carbide of a metal selected from the group consisting of titanium, vanadium, chromium, niobium, molybdenum, tantalum, and tungsten, as well as combinations thereof,
wherein the metal carbide-containing layer has a carbon content in a range of 40-65 atom %, and wherein the method comprises the following steps:
applying the base layer to the substrate, wherein, during the application of the base layer, a pulsed voltage is applied to the substrate in a range of −50 to −200 V; and
applying the metal carbide-containing layer over the base layer by means of magnetron sputtering, wherein the substrate is held under a constant voltage in a range of −50 to −200 V during the application of the metal carbide-containing layer, and wherein the metal carbide-containing layer is applied using a graphite target on a metal target separated from the graphite target.

2. The method according to claim 1, characterized in that the substrate is held in a range of −50 to −150 V during the application of the base layer.

3. The method according to claim 1, characterized in that the pulsed voltage applied to the substrate upon application of the base layer has a frequency in a range of 1 to 6 kHz, and a pulse length in a range of 30 to 100 μs.

4. The method according to claim 1, characterized in that the substrate is held under a constant voltage in a range of −80 to −200 V during the application of the metal carbide-containing layer.

5. The method according of claim 1, characterized in that the metal target is a titanium target.

6. The method according to claim 5, characterized in that the application of the titanium carbide-containing layer occurs in a pulsed mode, wherein the mode actuates the graphite target and the titanium target, respectively, with electrical pulses having a frequency in a range of 0.1-5 kHz.

7. The method according to claim 6, characterized in that the application of the titanium carbide-containing layer occurs in a pulsed mode, wherein a pulse of the pulsed mode has a pulse length in a range of 20-200 μs.

8. The method according to claim 5, characterized in that the graphite and titanium targets are each operated with a cathode energy in a range of 2 to 8 kW, during the application of the titanium carbide-containing layer.

9. The method according to claim 1, characterized in that the magnetron sputtering method is a high-power impulse magnetron sputtering (HiPIMS) method.

10. A coated body having a substrate and a coating arranged on the substrate, which coating comprises at least one base layer applied to the substrate and at least one metal carbide-containing layer arranged over the base layer,
wherein the base layer is formed from a nitride of aluminum and at least one further metal, wherein the further metal is selected from the group consisting of Ti, Cr, Si, Zr as well as combinations thereof,
wherein the metal carbide-containing layer comprises at least one carbide of a metal selected from the group consisting of titanium, vanadium, chromium, niobium, molybdenum, tantalum, and tungsten, as well as combinations thereof,
and wherein the metal carbide-containing layer has a carbon content in a range of 40-65 atom %,
wherein the body can be obtained by means of a method according to claim 1.

11. The coated body according to claim 10, characterized in that an intermediate layer is provided between the metal carbide-containing layer and the base layer, wherein the intermediate layer is formed from a carbonitride of aluminum and at least one further metal, wherein the further metal is selected from the group consisting of Ti, Cr, Si, Zr, as well as combinations thereof.

12. The coated body according to claim 11, characterized in that the intermediate layer is formed from AlTiCN.

13. The coated body according to claim 11, characterized in that the intermediate layer comprises at least one exchange layer of a carbonitride layer and a nitride layer arranged over the carbonitride layer, wherein the carbonitride layer is formed from a carbonitride of aluminum and at least one further metal selected from the group consisting of Ti, Cr, Si, Zr, as well as combinations thereof, and wherein the nitride layer is formed from a nitride of aluminum and at least one further metal selected from the group consisting of Ti, Cr, Si, Zr, as well as combinations thereof.

14. The coated body according to claim 13, characterized in that the carbonitride layer is formed from AlTiCN and/or the nitride layer is formed from AlTiN.

15. The coated body according to claim 10, characterized in that an intermediate layer is provided between the metal carbide-containing layer and the base layer, wherein the intermediate layer is formed from a carbonitride a metal, wherein the metal is selected from the group consisting of Ti, Cr, Si, Zr, as well as combinations thereof.

16. The coated body according to claim 15, characterized in that the intermediate layer is formed from TiCN.

17. The coated body according to claim 15, characterized in that the intermediate layer comprises at least one exchange layer of a carbonitride layer and a nitride layer arranged over the carbonitride layer, wherein the carbonitride layer is formed from a carbonitride of a metal selected from the group consisting of Ti, Cr, Si, Zr, as well as combinations thereof, and wherein the nitride layer is formed from a nitride of aluminum and at least one further metal selected from the group consisting of Ti, Cr, Si, Zr, as well as combinations thereof.

18. The coated body according to claim 17, characterized in that the carbonitride layer is formed from TiCN and/or the nitride layer is formed from AlTiN.

19. The coated body according to claim 13, characterized in that the intermediate layer comprises 1 to 10 repetitions of the at least one exchange layer consisting of carbonitride layer and nitride layer.

20. The coated body according to claim 10, characterized in that the metal carbide-containing layer is a titanium carbide-containing layer.

21. The coated body according to claim 20, characterized in that the titanium carbide-containing layer has a plastic hardness in a range from 25 to 50 GPa.

22. The coated body according to claim 20, characterized in that the titanium carbide-containing layer has an elasticity modulus in a range from 200 to 500 GPa.

23. The coated body according to claim 10, characterized in that the substrate is a cutting insert or tool holder.

24. The coated body according to claim 23, characterized in that the substrate is a tool holder having a receiving space with at least one surface in direct contact with the tool when a tool is clamped into the tool holder, wherein the at least one surface bears the coating.

25. The coated body according to claim 24, characterized in that the at least one surface is a base surface, a torque transfer surface, an abutment surface, or a clamping surface.
